(19) United States
(12) Patent Application Publication
(10) Pub. No.: US 2009/0315068 A1
(43) Pub. Date: Dec. 24, 2009

(54) LIGHT EMITTING DEVICE

(75) Inventors: Hiroaki Oshio, Kanagawa-ken (JP); Reiji Ono, Kanagawa-ken (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/391,282

(22) Filed: Feb. 24, 2009

(30) Foreign Application Priority Data
Jun. 18, 2008 (JP) 2008-159120

(51) Int. Cl. H01L 27/00

(52) U.S. Cl. 257/103; 257/E27.001

(57) ABSTRACT

A light emitting device includes: a light emitting element; a first lead including a die pad portion at its one end portion, the light emitting element being bonded to the die pad portion; a second lead with its one end portion being opposed to the one end portion of the first lead; and a resin molded body including a recess with at least part of the die pad portion being exposed to the bottom thereof so that emission light from the light emitting element can be emitted upward, a lower surface with at least part of the lower surface of the first lead and at least part of the lower surface of the second lead being exposed thereto, and a lateral surface with at least part of the lateral surface of the die pad portion being exposed thereto, the resin molded body embedding the first lead and the second lead so that the other end portion of the first lead and the other end portion of the second lead are projected in directions opposite to each other. The at least part of the lateral surface of the die pad portion which is exposed is located on a first plane which is generally coplanar with the lateral surface of the other end portion of the first lead and the lateral surface of the other end portion of the second lead.

### CROSS-REFERENCE TO RELATED APPLICATIONS

This application is based upon and claims the benefit of priority from the prior Japanese Patent Application No. 2008-159120, filed on Jun. 18, 2008; the entire contents of which are incorporated herein by reference.

### BACKGROUND OF THE INVENTION

1. Field of the Invention

This invention relates to a light emitting device.

2. Background Art

Semiconductor light emitting devices capable of emitting light in the visible wavelength range are used for backlight sources and indicators of car-mounted and other illumination devices and image display devices. In these applications, surface-mounted devices facilitate high-density packaging on a substrate or other mounting member.

For example, in application to the backlight source of an image display device, the display plate is placed on the light guide plate so that the display screen faces upward. To apply light to the lateral side of the light guide plate along the surface of the mounting member, it is preferable that the light extraction surface of the light emitting device be opposed to the lateral surface of the light guide plate. In this case, the light emitting device attached to the mounting substrate is also called the light emitting device of the side-view type because its lateral surface serves as the light extraction surface.

On the other hand, in normal light emitting devices, the upper surface of the light emitting device with respect to the mounting surface serves as the light extraction surface. If the light emitting device has a structure capable of allowing its lower surface and one lateral surface to be attached to the mounting member, light can be emitted to both the upside and the lateral side of the mounting member. Thus, the device is easy to use and facilitates commonality of components.

JP-A-2004-335740 (Kokai) discloses a technique related to a light emitting diode that can be mounted on a motherboard face up or sideways. This technique provides a light emitting diode having high heat dissipation and productivity by bending work of the lead frame so that the lead is exposed to the outer lateral surface of the resin and to the bottom and inner lateral surface of the resin recess.

However, even in this technique, heat dissipation is not sufficient and puts limitations on high-current operation. Furthermore, the process for manufacturing the lead frame is complicated by the bending work and insufficient in volume productivity.

### SUMMARY OF THE INVENTION

According to an aspect of the invention, there is provided a light emitting device including: a light emitting element; a first lead including a die pad portion at its one end portion, the light emitting element being bonded to the die pad portion; a second lead with its one end portion being opposed to the one end portion of the first lead; and a resin molded body including a recess with at least part of the die pad portion being exposed to the bottom thereof so that emission light from the light emitting element can be emitted upward, a lower surface with at least part of the lower surface of the first lead and at least part of the lower surface of the second lead being exposed thereto, and a lateral surface with at least part of the lateral surface of the die pad portion being exposed thereto, the resin molded body embedding the first lead and the second lead so that the other end portion of the first lead and the other end portion of the second lead are projected in directions opposite to each other, the at least part of the lateral surface of the die pad portion which is exposed being located on a first plane which is generally coplanar with the lateral surface of the other end portion of the first lead and the lateral surface of the other end portion of the second lead.

According to another aspect of the invention, there is provided A light emitting device including: a light emitting element made of nitride semiconductor; a first lead including a die pad portion at its one end portion, the light emitting element being bonded to the die pad portion; a second lead with its one end portion being opposed to the one end portion of the first lead; a resin molded body including a recess with at least part of the die pad portion being exposed to the bottom thereof so that emission light from the light emitting element can be emitted upward, a lower surface with at least part of the lower surface of the first lead and at least part of the lower surface of the second lead being exposed thereto, and a lateral surface with at least part of the lateral surface of the die pad portion being exposed thereto, the resin molded body embedding the first lead and the second lead so that the other end portion of the first lead and the other end portion of the second lead are projected in directions opposite to each other; and a sealing resin mixed with phosphor that can absorb the emission light and emit wavelength-converted light having a longer wavelength than the emission light, the sealing resin being filled in the recess so as to cover the light emitting element, the at least part of the lateral surface of the die pad portion which is exposed being located on a first plane which is generally coplanar with the lateral surface of the other end portion of the first lead and the lateral surface of the other end portion of the second lead, and mixed light of the emission light and the wavelength-converted light being able to be emitted.

According to another aspect of the invention, there is provided A light emitting device including: a light emitting element; a first lead including a die pad portion at its one end portion, the die pad portion including a recess in its upper surface, the recess including a bottom surface to which the light emitting element can be bonded and an inner surface at which part of emission light from the light emitting element can be reflected upward; a second lead with its one end portion being opposed to the one end portion of the first lead; and a resin molded body including a recess with at least part of the die pad portion being exposed to the bottom thereof so that the emission light from the light emitting element can be emitted upward, a lower surface with at least part of the lower surface of the first lead and at least part of the lower surface of the second lead being exposed thereto, and a lateral surface with at least part of the lateral surface of the die pad portion being exposed thereto, the resin molded body embedding the first lead and the second lead so that the other end portion of the first lead and the other end portion of the second lead are projected in directions opposite to each other, the at least part of the lateral surface of the die pad portion which is exposed being located on a first plane which is generally coplanar with the lateral surface of the other end portion of the first lead and the lateral surface of the other end portion of the second lead.

### BRIEF DESCRIPTION OF THE DRAWINGS

FIGS. 1A and 1B are schematic views of a light emitting device according to a first embodiment of the invention;

FIGS. 2A to 2F are schematic views illustrating this embodiment in more detail;

FIG. 3 shows a flow chart of a method for manufacturing;

FIGS. 4A to 4D are schematic views of the device attached to a mounting member;

FIGS. 5A and 5B are schematic views of a light emitting device according to a second embodiment; and

FIGS. 6A to 6E are schematic views of a light emitting device according to a third embodiment.

### DETAILED DESCRIPTION OF THE INVENTION

Embodiments of the invention will now be described with reference to the drawings.

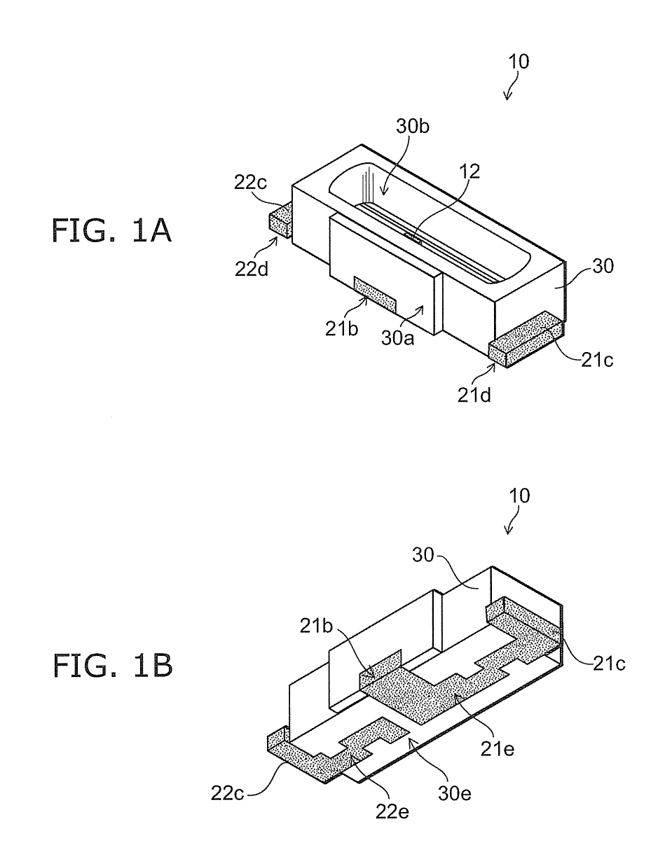

FIG. 1 is a schematic view of a light emitting device according to a first embodiment of the invention. More specifically, FIG. 1A is a perspective view from obliquely above, and FIG. 1B is a perspective view from obliquely below. It is noted that FIG. 1 shows the situation before the resin sealing process.

A first lead 21 and a second lead 22 are embedded in a (resin) molded body 30 illustratively made of a thermoplastic or thermoset resin. The first lead 21 has an end portion 21c projected from the molded body 30, and the second lead 22 has an end portion 22c projected from the molded body 30. The end portions 21c and 22c are generally collinear and projected in opposite directions.

The molded body 30 has a recess 30b. Each upper surface of the first lead 21 and the second lead 22 is exposed to the bottom of the recess 30b. A light emitting element 12 made of semiconductor is bonded to the exposed surface of the first lead 21 in the recess 30b.

On the lateral surface side of the molded body 30, the lateral surface 21d of the end portion 21c of the first lead 21, the lateral surface 22d of the end portion 22c of the second lead 22, and the lateral surface 21b of the die pad portion of the first lead 21 to which the light emitting element 12 is to be bonded constitute a first plane, and hence is easily attached to the surface of the mounting member.

Furthermore, the lower surface 21e of the first lead 21 and the lower surface 22e of the second lead 22 are exposed to the lower surface 30e of the molded body 30e and generally coplanar. Hence, the device can be tightly attached to the surface of the mounting member.

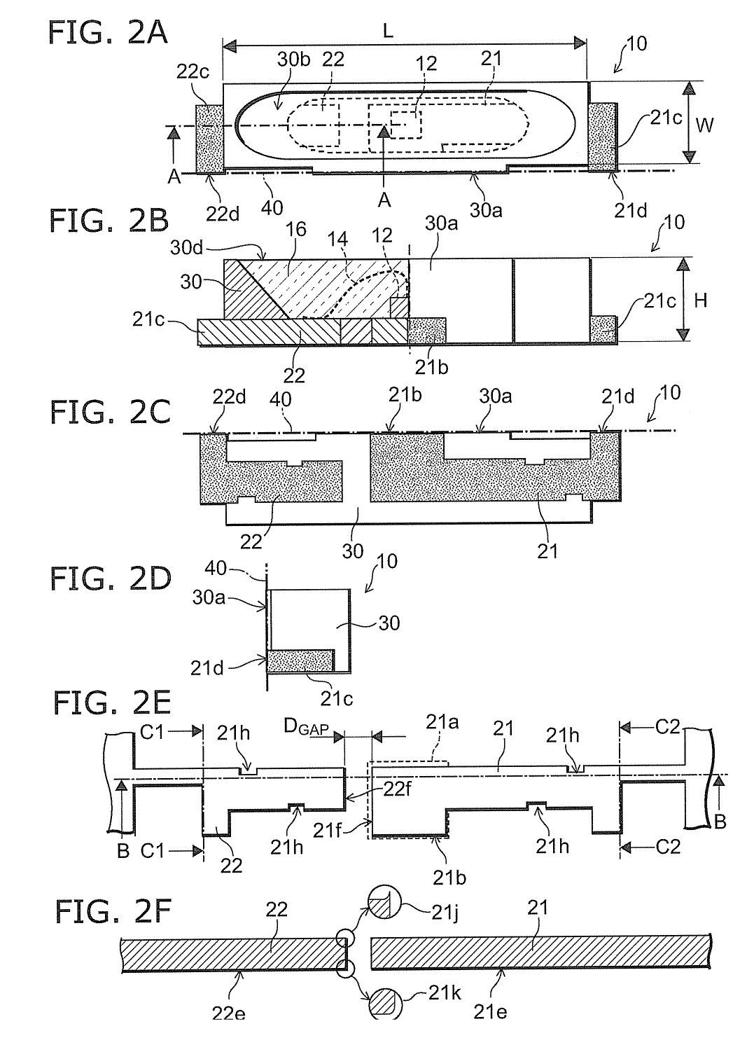

FIG. 2 is a schematic view illustrating this embodiment in more detail. More specifically, FIG. 2A is a plan view, FIG. 2B is a partial cross-sectional view taken along line A-A, FIG. 2C is a bottom view, FIG. 2D is a side view, FIG. 2E is a plan view of the lead frame, and FIG. 2F is a cross-sectional view of the lead frame taken along line B-B.

As shown in FIGS. 2A and 2B, one end portion 21f of the first lead 21 and one end portion 22f of the second lead 22 are opposed to each other across the molded body 30. The other end portion 21c of the first lead 21 is projected from the molded body 30, and the other end portion 22c of the second lead 22 is also projected from the molded body 30. The end portion 21c, 22c is projected at its tip and easily connected to the conductive portion of the mounting member.

The molded body 30 has a recess 30b. Part of the upper surface of the first lead 21, including the die pad portion 21a for the light emitting element 12, and part of the upper surface of the second lead 22, including a wire bonding region, are exposed to the bottom of the recess 30b. A sealing resin 16 illustratively made of silicone is filled in the recess 30b so as to cover the light emitting element 12 made of semiconductor and a bonding wire 14.

Here, phosphors can be mixed in the sealing resin 16 to obtain white light, for example, as mixed light of the emission light from the light emitting element 12 and the wavelength-converted light produced by the phosphors. The opening end 30d of the recess 30b generally coincides with the surface of the sealing resin 16 and serves as the light extraction side.

In the case where the light emitting device 10 is used in applications such as a backlight source, it is preferable that in the opening end 30d of the recess 30b, the length along which the first and second lead 21, 22 are juxtaposed be larger than the length perpendicular to the juxtaposed direction. In this case, for example, the length L of the lead in its extending direction can be 3 to 5 mm, the width W perpendicular thereto can be 0.5 to 2 mm, and the height H can be 0.5 to 1.5 mm. It is understood that the shape of the opening end 30d is not limited thereto, but its design can be freely adapted to the purpose.

As shown in FIG. 2C, in the lower surface of the light emitting device 10, the lower surface 21e of the first lead 21 and the lower surface 22e of the second lead 22 are exposed to the lower surface 30e of the molded body 30, and are generally coplanar. Hence, the device can be tightly bonded to the surface of the mounting member across a solder material. If the lower surface of the die pad portion 21a of the semiconductor light emitting element 12 is bonded to the conductive portion of the surface of the mounting member illustratively by soldering, then the heat dissipation path is shortened, and thermal resistance can be reduced.

Furthermore, the volume productivity of the lead frame can be improved by a multi-production technique as shown in FIG. 2E. Use of a copper-based alloy for the material of the lead frame can further reduce the thermal resistance. If the lead frame is thickened, the thermal resistance can be further reduced, but the spacing DGAP of the punch-out portion needs to be expanded. Hence, for example, the lead frame thickness is preferably in the range of 0.15 to 0.4 mm, and more preferably in the range of 0.2 to 0.3 mm. Preferably, a notch 21h is provided in the lead frame region embedded in the resin, because “biting” between the lead frame and the resin molded body 30 can increase bonding strength.

On the other hand, in the configuration in which the press surface of the lead frame is exposed to the lower surface 30e side of the molded body 30, the two end portions of the leads opposed to each other are projected to the surface opposite to the press surface as shown by 21j, 21k. Hence, protrusion of the lead to the exposed surface side can be prevented to improve tight contact with the mounting member.

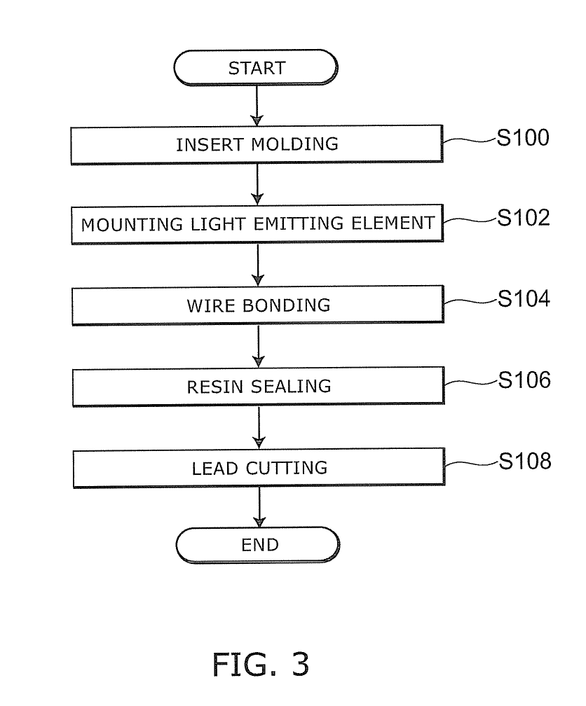

FIG. 3 shows a flow chart of the method for manufacturing a light emitting device according to this embodiment.

In advance, a coating in which, for example, Ni/Pd/Au are laminated in this order, is applied to the lead frame. This coating facilitates increasing the reflectance of the lead frame surface and increasing the solder bonding strength of the end portions 21c, 22c and the exposed surface 21b of the die pad portion 21a. If Ag selective plating or the like is further applied to a region desired to have higher light reflectance, the emission light is reflected upward near the light emitting element 12, and the light extraction efficiency can be easily increased.

First, the lead frame shown in FIGS. 2E and 2F is insert molded illustratively using a thermoplastic resin (S100). For example, in the case where the glass transition temperature of the thermoplastic resin is generally 100° C., the mold temperature is set to generally 130° C. The thermoplastic resin can illustratively be a nylon resin such as polyphthalamide (PPA). It is noted that powder of a metal oxide such as potassium titanate can be mixed in the thermoplastic resin to increase reflectance at the sidewall and the bottom surface of the recess 30b.

The thermal expansion coefficient of the thermoplastic resin thus mixed with potassium titanate and the like can be approximated to the thermal expansion coefficient of the lead frame, and the tight contact between the lead and the resin molded body can be easily maintained even in the solder reflow process at a temperature of e.g. 260° C. Furthermore, the allowable temperature limit at which the thermoplastic resin starts plastic deformation can be set to generally 300° C. so that it is resistant to the solder reflow process.

A light emitting element 12 is bonded to the die pad portion 21a of the first lead 21 illustratively using a conductive adhesive (S102). After the conductive adhesive is cured, wire bonding is performed (S104).

A liquid sealing resin 16 is filled in the recess 30b of the molded body 30 and cured (S106). In the case where white light is desired, the liquid sealing resin 16 is dispersed with phosphors. For example, in the case where the emission light of the light emitting element 12 has a blue wavelength, a silicate-based yellow phosphor can be mixed in the liquid sealing resin 16 and applied to the inside of the recess 30b.

Subsequently, the lead frame is cut along line C1-C1 and line C2-C2 of FIG. 2E into individual light emitting devices 10 (S108). It is noted that the insert molding process may follow the process of mounting the light emitting element 12. Use of a thermosetting resin for the above resin facilitates preventing deformation after heat curing at approximately 200° C.

Typically, in a light emitting device of the lateral emission type having an SMD (surface-mounted device) structure, the lead frame is often subjected to bending work. A smaller thickness of the lead frame, although facilitating bending work, is not preferable because it increases thermal resistance. In contrast, the manufacturing method of this embodiment scarcely needs bending work of the lead frame, and hence can simplify the assembling process. Thus, this embodiment provides a method for manufacturing a light emitting device with high volume productivity. Furthermore, the thickness of the lead frame is easily increased to reduce thermal resistance.

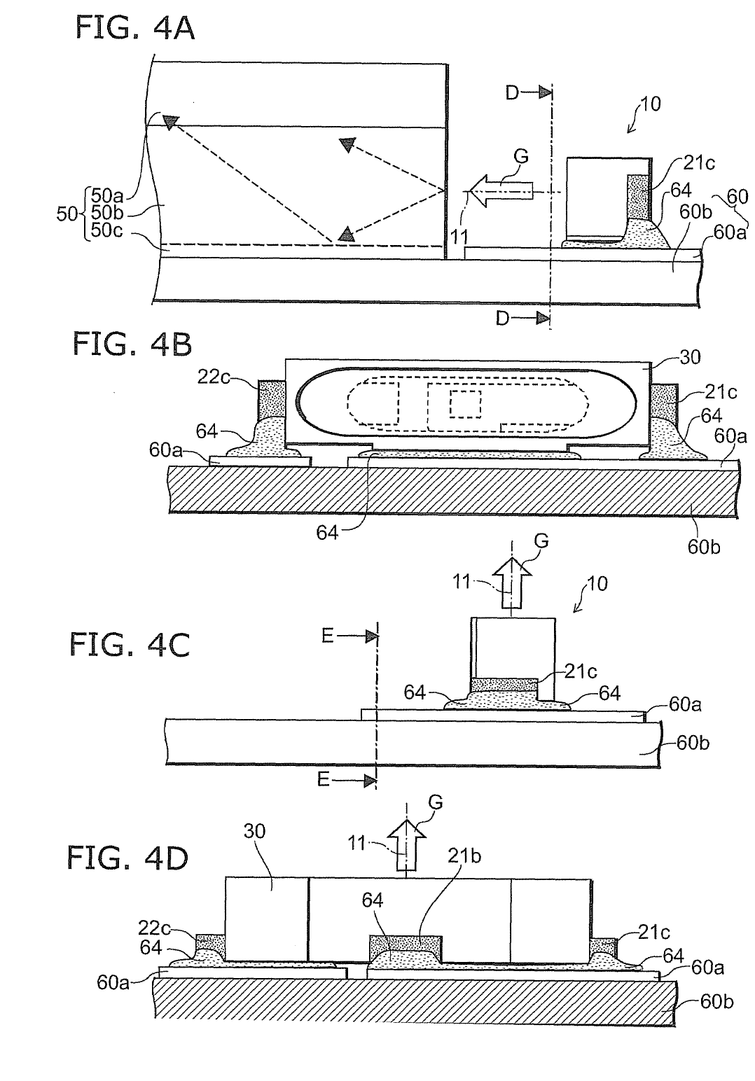

FIG. 4 is a schematic view in which the light emitting device according to this embodiment is attached to a mounting member. More specifically, FIG. 4A shows the device used as a laterally emitting device for the backlight source of an image display device, and FIG. 4B shows the light extraction side along line D-D. FIG. 4C shows the device used as a top-emitting device as viewed from the first lead 21 side, and FIG. 4D shows the lateral surface side along line E-E.

In FIG. 4A, the light emitting device 10 according to this embodiment is soldered illustratively by a reflow process on a mounting member 60 in which a conductive portion 60a is provided on the surface of a substrate 60b. On the other hand, the image display device 50 includes a display portion 50a illustratively made of liquid crystal, a light guide plate 50b for guiding light to the display portion 50a, and a reflecting plate 50c configured so that the downward emission light from the semiconductor light emitting device 10 is reflected upward to the display portion 50a. The image display device 50 is placed on the mounting member 60 so that the lateral surface of the light guide plate 50b is generally opposed to the opening end 30d of the light emitting device 10.

As shown in FIG. 2, the lateral surface 21b of the die pad portion 21a of the first lead 21 exposed to the lateral surface 30a of the molded body 30, the lateral surface 21d of the end portion 21c of the first lead 21 projected from the molded body 30, and the lateral surface 22d of the end portion 22c of the second lead 22 projected from the molded body 30 constitute a first plane 40. Hence, as shown in FIGS. 4A and 4B, the lateral surface 21b, the lateral surface 21d, and the lateral surface 22d can be bonded to the conductive portion 60a of the surface of the mounting member 60 using a solder material 64. In this case, the end portions 21c, 22c can be soldered so that two or more surfaces including the lateral surfaces thereof are covered. For example, bonding strength is easily increased by soldering at three surfaces.

The die pad portion 21a can be bonded, at least in its lateral surface 21b, to the conductive portion 60a of the mounting member 60 by the solder material 64. Hence, the thermal resistance can be easily made lower than 200° C./W, and can illustratively be decreased to 110° C./W. If the lower surface or the lateral surface of the die pad portion 21a is not soldered, the heat dissipation is difficult to improve, and the thermal resistance is illustratively as high as 350 to 500° C./W. This makes it difficult to increase the operating current of the light emitting device 10 to 20 mA or more, and the brightness is not easy to increase. In contrast, in this embodiment, improvement in heat dissipation allows the operating current to be 40 mA or more, which facilitates increasing the brightness.

The lateral surface 21b of the die pad portion 21a may indeed be projected from the lateral surface 30a of the molded body 30, but the device is then bonded to and supported on the mounting member 60 at three points on a line, such as the two lateral surfaces 21d, 22d of the end portions 21c, 22c as well as the lateral surface 21b. This makes it difficult to keep the optical axis 11 horizontal with high accuracy. In contrast, if the lateral surface 21b is not projected so that the lateral surface 30a of the molded body 30 is located on the first plane, the lateral surface 30a serves as the fourth supporting point with respect to the surface of the mounting member 60 and facilitates accurately aligning the optical axis 11 of the emission light G with the direction generally parallel to the surface of the mounting member 60.

In application to a backlight source, a plurality of light emitting devices 10 are arranged in accordance with the size of the image. In this case, the number of light emitting devices 10 can be reduced by opposing the length L of the opening end 30d to the lateral surface of the light guide plate 50b in a generally parallel configuration.

Unless the emission light G is accurately incident on the lateral surface of the light guide plate 50b, the brightness is difficult to keep uniform in the display portion 50a and the like. In contrast, the light emitting device 10 according to this embodiment is easily soldered to the mounting member 60 with high accuracy and can realize an image display device 50 with reduced unevenness in brightness.

Furthermore, in FIG. 4C showing use as a top-emitting device, the lower surface 21e of the first lead 21 and the lower surface 22e of the second lead 22 are exposed to the lower surface 30e of the molded body 30. The first lead 21 and the second lead 22 are easily soldered at the vertical lateral surface besides the lower surface 21e, 22e, and bonding strength can be increased.

Furthermore, as shown in FIGS. 4C and 4D, the heat dissipation path from the die pad portion 21a of the light emitting element 12 to the conductive portion 60a of the mounting member 60 is shortened. This facilitates decreasing the thermal resistance to e.g. 200° C./W or less and increasing the operating current to 40 mA or more.

Furthermore, the first and second lead 21, 22, which are generally flat, are exposed to the lower surface of the light emitting device 10. Hence, the optical axis 11 can be easily made generally perpendicular to the surface of the mounting member 60. Thus, this embodiment provides a light emitting device 10 of the top-emitting type having an optical axis 11 vertically oriented with high accuracy.

Thus, light can be emitted to both the upside and the lateral side of the mounting member. Hence, this embodiment can provide a light emitting device which is easy to use and facilitates commonality of components.

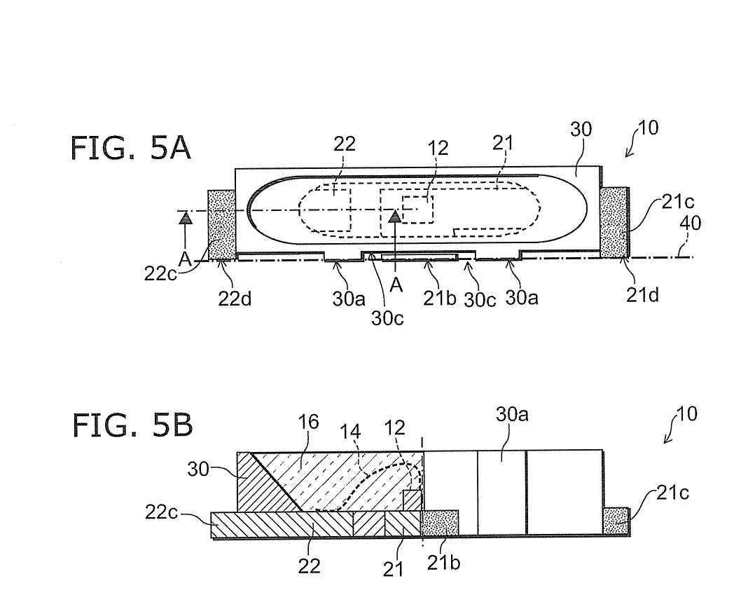

FIG. 5 is a schematic view of a light emitting device according to a second embodiment. More specifically, FIG. 5A is a plan view, and FIG. 5B is a partial cross-sectional view taken along line A-A.

The lateral surface 30a of the molded body 30 has a notch 30c in the neighborhood of the lateral surface 21b of the first lead 21. Part of the die pad portion 21a is projected from this notch 30c. Such a projection allows the device to be soldered so that the solder wraps around the upper surface, the lateral surface, and the lower surface of the die pad portion 21a, whether the device is used as a top-emitting device or a laterally emitting device. Thus, bonding strength can be increased.

It is noted that as shown in FIG. 5A, the lateral surface 30a located on the first plane 40 is present on both outer sides of the notch 30c as viewed from above. Hence, in the case where the device is attached as a laterally emitting device, the device is supported at five points with respect to the surface of the mounting member 60. Thus, the optical axis can be kept horizontal with high accuracy.

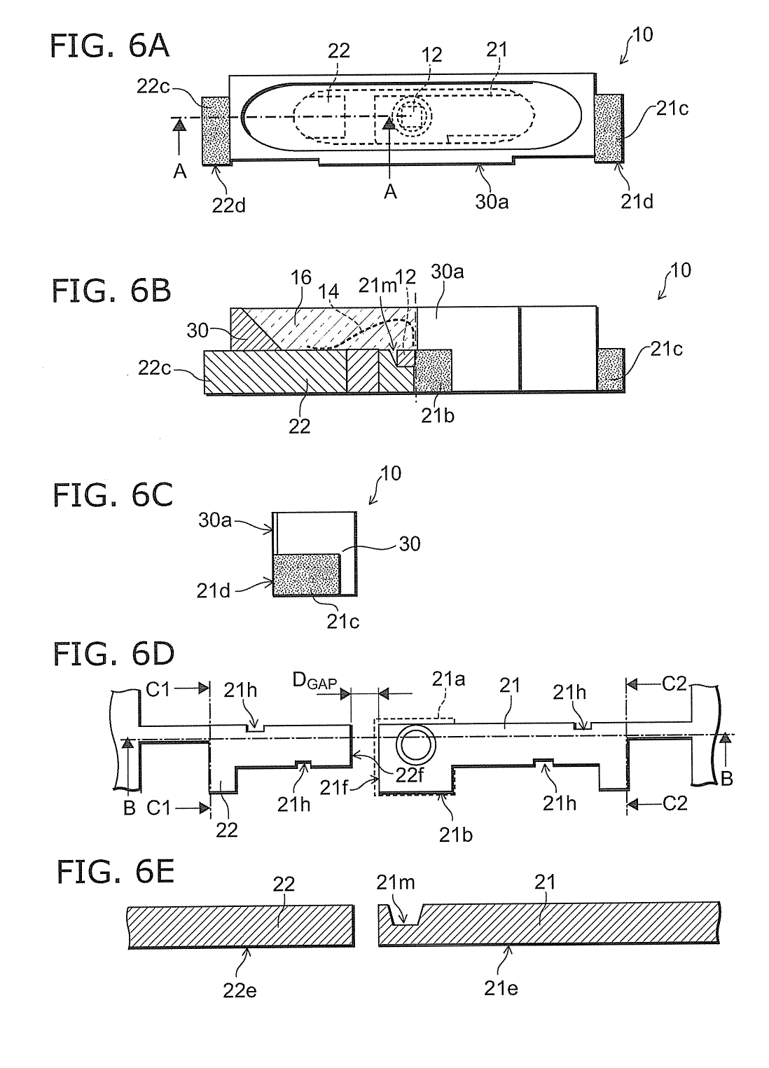

FIG. 6 is a schematic view of a light emitting device according to a third embodiment. More specifically, FIG. 6A is a plan view, FIG. 6B is a partial cross-sectional view taken along line A-A, FIG. 6C is a side view, FIG. 6D is a plan view of the lead frame, and FIG. 6E is a cross-sectional view of the lead frame taken along line B-B.

In this embodiment, a recess 21m is formed in the first lead 21 illustratively by press working, and a light emitting element 12 is bonded to the bottom surface of the recess 21m. The sidewall of the recess 21m serves as a reflecting surface of the emission light to enhance upward light. To provide the recess 21m, the first lead 21 is designed to have a large thickness, e.g., 0.25 to 0.4 mm. This facilitates reducing thermal resistance.

The resin molded body 30 and the sealing resin 16 filled in its recess 30b may be discolored by absorbing UV to visible light. Hence, in the neighborhood of the light emitting element 12 where the light intensity is high, the emission light is preferably reflected upward to increase the efficiency of light extraction to the outside. According to this embodiment, the inner surface of the recess 21m of the first lead 21 is turned into a light reflecting surface illustratively by Ag plating. This facilitates increasing the light extraction efficiency and preventing discoloration of the resin. Thus, a high-brightness light emitting device is provided.

The light emitting element 12 can be illustratively made of a material based on Inₓ(Al_{y}Ga_{1-y})₁₋ₓN (where 0≦x≦1, 0≦y≦1), which can emit UV to green light, or a material based on Inₓ(Al_{y}Ga_{1-y})₁₋ₓP (where 0≦x≦1, 0≦y≦1), which can emit visible to infrared light.

As described above, the first to third embodiment provide a light emitting device having low thermal resistance and being capable of emitting light vertically upward and horizontally with respect to the surface of the mounting member. The light emitting device according to the present embodiments can be used for backlight sources and indicators of car-mounted and other illumination devices and image display devices.

The embodiments of the invention have been described with reference to the drawings. However, the invention is not limited to these embodiments. The shape, material, size, layout and the like of the light emitting element, molded body, resin, and lead frame constituting the embodiments of the invention can be modified by those skilled in the art, and such modifications are encompassed within the scope of the invention as long as they do not depart from the spirit of the invention.

1. A light emitting device comprising:
a light emitting element;
a first lead including a die pad portion at its one end portion, the light emitting element being bonded to the die pad portion;
a second lead with its one end portion being opposed to the one end portion of the first lead; and
a resin molded body including a recess with at least part of the die pad portion being exposed to the bottom thereof so that emission light from the light emitting element can be emitted upward, a lower surface with at least part of the lower surface of the first lead and at least part of the lower surface of the second lead being exposed thereto, and a lateral surface with at least part of the lateral surface of the die pad portion being exposed thereto, the resin molded body embedding the first lead and the second lead so that the other end portion of the first lead and the other end portion of the second lead are projected in directions opposite to each other,
the at least part of the lateral surface of the die pad portion which is exposed being located on a first plane which is generally coplanar with the lateral surface of the other end portion of the first lead and the lateral surface of the other end portion of the second lead.

2. The device according to claim 1, wherein
the lateral surface of the resin molded body includes a projection extending from the lower surface to the upper surface of the resin molded body, and
the surface of the projection is located on the first plane.

3. The device according to claim 2, wherein the at least part of the lateral surface of the die pad portion is projected from the lateral surface of the resin molded body that constitutes a non-forming region of the projection.

4. The device according to claim 1, wherein the length of the opening end of the recess in the direction along which the first and second lead are juxtaposed is larger than the length of the opening end of the recess in a direction perpendicular to the juxtaposed direction.

5. The device according to claim 1, further comprising:
a sealing resin mixed with phosphor that can absorb the emission light and emit wavelength-converted light having a longer wavelength than the emission light, the sealing resin being filled in the recess so as to cover the light emitting element,
wherein mixed light of the emission light and the wavelength-converted light can be emitted.

6. The device according to claim 1, wherein the resin molded body is made of a thermoplastic resin or a thermoset resin.

7. The device according to claim 6, wherein a metal oxide is mixed in the resin molded body.

8. The device according to claim 1, wherein the first and second lead are made of an alloy containing at least one of copper and iron.

9. A light emitting device comprising:
a light emitting element made of nitride semiconductor;
a first lead including a die pad portion at its one end portion, the light emitting element being bonded to the die pad portion;
a second lead with its one end portion being opposed to the one end portion of the first lead;
a resin molded body including a recess with at least part of the die pad portion being exposed to the bottom thereof so that emission light from the light emitting element can be emitted upward, a lower surface with at least part of the lower surface of the first lead and at least part of the lower surface of the second lead being exposed thereto, and a lateral surface with at least part of the lateral surface of the die pad portion being exposed thereto, the resin molded body embedding the first lead and the second lead so that the other end portion of the first lead and the other end portion of the second lead are projected in directions opposite to each other; and
a sealing resin mixed with phosphor that can absorb the emission light and emit wavelength-converted light having a longer wavelength than the emission light, the sealing resin being filled in the recess so as to cover the light emitting element,
the at least part of the lateral surface of the die pad portion which is exposed being located on a first plane which is generally coplanar with the lateral surface of the other end portion of the first lead and the lateral surface of the other end portion of the second lead, and
mixed light of the emission light and the wavelength-converted light being able to be emitted.

10. The device according to claim 9, wherein the length of the opening end of the recess in the direction along which the first and second lead are juxtaposed is larger than the length of the opening end of the recess in a direction perpendicular to the juxtaposed direction.

11. The device according to claim 9, wherein the resin molded body is made of a thermoplastic resin or a thermoset resin.

12. The device according to claim 11, wherein a metal oxide is mixed in the resin molded body.

13. The device according to claim 9, wherein the first and second lead are made of an alloy containing at least one of copper and iron.

14. A light emitting device comprising:
a light emitting element;
a first lead including a die pad portion at its one end portion, the die pad portion including a recess in its upper surface, the recess including a bottom surface to which the light emitting element can be bonded and an inner surface at which part of emission light from the light emitting element can be reflected upward;
a second lead with its one end portion being opposed to the one end portion of the first lead; and
a resin molded body including a recess with at least part of the die pad portion being exposed to the bottom thereof so that the emission light from the light emitting element can be emitted upward, a lower surface with at least part of the lower surface of the first lead and at least part of the lower surface of the second lead being exposed thereto, and a lateral surface with at least part of the lateral surface of the die pad portion being exposed thereto, the resin molded body embedding the first lead and the second lead so that the other end portion of the first lead and the other end portion of the second lead are projected in directions opposite to each other,
the at least part of the lateral surface of the die pad portion which is exposed being located on a first plane which is generally coplanar with the lateral surface of the other end portion of the first lead and the lateral surface of the other end portion of the second lead.

15. The device according to claim 14, wherein
the lateral surface of the resin molded body includes a projection extending from the lower surface to the upper surface of the resin molded body, and
the surface of the projection is located on the first plane.

16. The device according to claim 14, wherein the at least part of the lateral surface of the die pad portion is projected from the lateral surface of the resin molded body that constitutes a non-forming region of the projection.

17. The device according to claim 14, further comprising:
a sealing resin mixed with phosphor that can absorb the emission light and emit wavelength-converted light having a longer wavelength than the emission light, the sealing resin being filled in the recess of the resin molded body so as to cover the light emitting element,
wherein mixed light of the emission light and the wavelength-converted light can be emitted.

18. The device according to claim 17, wherein the length of the opening end of the recess of the resin molded body in the direction along which the first and second lead are juxtaposed is larger than the length of the opening end of the recess of the resin molded body in a direction perpendicular to the juxtaposed direction.

19. The device according to claim 14, wherein the resin molded body is made of a thermoplastic resin or a thermoset resin.

20. The device according to claim 14, wherein the first and second lead are made of an alloy containing at least one of copper and iron.
